(19) United States
(12) Patent Application Publication
(10) Pub. No.: US 2025/0241153 A1
(43) Pub. Date: Jul. 24, 2025

(54) DISPLAY DEVICE

(71) Applicant: Samsung Display Co., LTD., Yongin-si (KR)

(72) Inventors: Dongmin LEE, Yongin-si (KR); Jongoh SEO, Yongin-si (KR); Donggyu JIN, Yongin-si (KR)

(21) Appl. No.: 19/027,239

(22) Filed: Jan. 17, 2025

(30) Foreign Application Priority Data
Jan. 22, 2024 (KR) 10-2024-0009787

(51) Int. Cl. H10K 59/131; H10K 59/12; H10K 102/00

(52) U.S. Cl. CPC H10K 59/131; H10K 59/1201; H10K 2102/351

(57) ABSTRACT

A display apparatus includes: a substrate, a first lower metal layer disposed on the substrate, a second lower metal layer disposed on the first lower metal layer and forming a step with an edge portion of the first lower metal layer, a buffer layer disposed on the second lower metal layer, and a semiconductor layer disposed on the buffer layer. A thickness of the semiconductor layer at an edge where a top surface of the buffer layer farthest from the substrate and a lateral surface of the buffer layer meet each other is about 320 Å to about 480 Å.

This application claims priority to Korean Patent Application No. 10-2024-0009787, filed on Jan. 22, 2024, and all the benefits accruing therefrom under 35 U.S.C. § 119, the content of which in its entirety is herein incorporated by reference.

### BACKGROUND

### 1. Field

One or more embodiments relate to a display apparatus.

### 2. Description of the Related Art

Display apparatuses visually display data. Display apparatuses can provide images by using light-emitting diodes. Applications of display apparatuses have become diversified, and various design efforts for improving the quality of display apparatuses have been made.

### SUMMARY

One or more embodiments include a display apparatus.

Additional aspects will be set forth in part in the description which follows and, in part, will be apparent from the description, or may be learned by practice of the presented embodiments of the disclosure

According to one or more embodiments, a display apparatus includes: a substrate, a first lower metal layer disposed on the substrate, a second lower metal layer disposed on the first lower metal layer and forming a step with an edge portion of the first lower metal layer, a buffer layer disposed on the second lower metal layer, and a semiconductor layer disposed on the buffer layer. A thickness of the semiconductor layer at an edge where a top surface of the buffer layer farthest from the substrate and a lateral surface of the buffer layer meet each other is about 320 angstroms (Å) to about 480 Å.

A lateral surface of the first lower metal layer may be provided as an inclined surface.

A lateral surface of the second lower metal layer may be provided as an inclined surface.

The lateral surface of the first lower metal layer and the lateral surface of the second lower metal layer may have positive taper shapes.

A lateral surface of the semiconductor layer may be provided as an inclined surface.

The longest length of the first lower metal layer in a first direction may be greater than the longest length of the second lower metal layer in the first direction.

The first lower metal layer may include titanium (Ti), and the second lower metal layer may include molybdenum (Mo).

The first lower metal layer may include molybdenum (Mo), and the second lower metal layer may include titanium (Ti).

The display apparatus may further include a third lower metal layer disposed on the second lower metal layer and forming a step with an edge portion of the second lower metal layer.

A lateral surface of the first lower metal layer, a lateral surface of the second lower metal layer, and a lateral surface of the third lower metal layer may be provided as inclined surfaces.

The lateral surface of the first lower metal layer, the lateral surface of the second lower metal layer, and the lateral surface of the third lower metal layer may have positive taper shapes.

The longest length of the first lower metal layer in a first direction may be greater than the longest length of the second lower metal layer in the first direction, and the longest length of the second lower metal layer in the first direction may be greater than the longest length of the third lower metal layer in the first direction.

The first lower metal layer and the third lower metal layer may include molybdenum (Mo), and the second lower metal layer may include titanium (Ti).

The first lower metal layer and the third lower metal layer may include titanium (Ti), and the second lower metal layer may include molybdenum (Mo).

According to one or more embodiments, a method of manufacturing a display apparatus includes disposing a first lower metal layer-forming material on a substrate, disposing a second lower metal layer-forming material on the first lower metal layer-forming material, performing a first etching operation of forming a first lower metal layer by etching at least a portion of the first lower metal layer-forming material, performing a second etching operation of forming a second lower metal layer by further etching at least a portion of the second lower metal layer-forming material, forming a buffer layer on the first lower metal layer and the second lower metal layer, and forming a semiconductor layer on the buffer layer. A thickness of the semiconductor layer at an edge where a top surface of the buffer layer farthest from the substrate and a lateral surface of the buffer layer meet each other is about 320 Å to about 480 Å, and the first lower metal layer-forming material and the second lower metal layer-forming material are different from each other.

The first etching operation may include disposing a first photoresist on at least a portion of the second lower metal layer-forming material, forming the first lower metal layer by etching a portion of the first lower metal layer-forming material on which the first photoresist is not disposed, etching a portion of the second lower metal layer-forming material on which the first photoresist is not disposed, and removing the first photoresist.

The second etching operation may include disposing a second photoresist on at least a portion of the second lower metal layer-forming material, forming the second lower metal layer by etching a portion of the second lower metal layer-forming material on which the second photoresist is not disposed, and removing the second photoresist.

Respective lateral surfaces of the first lower metal layer and the second lower metal layer may be provided as inclined surfaces, and the lateral surface of the first lower metal layer and the lateral surface of the second lower metal layer may have positive taper shapes.

A lateral surface of the semiconductor layer may be provided as an inclined surface.

The first lower metal layer-forming material may include molybdenum (Mo), and the second lower metal layer-forming material may include titanium (Ti). Alternatively, the first lower metal layer-forming material may include titanium (Ti), and the second lower metal layer-forming material may include molybdenum (Mo).

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is a schematic equivalent circuit diagram of one subpixel circuit included in a display apparatus according to an embodiment;

FIG. 3 is a schematic cross-sectional view of a portion of a display apparatus;

FIG. 4 is a magnified view schematically showing at least a portion of the cross-section of a display apparatus according to an embodiment;

FIG. 5 is an enlarged schematic view of at least a portion of the cross-section of the display apparatus of FIG. 4;

FIG. 6 schematically shows a plan view and a cross-sectional view when a lower metal layer is provided as a single layer;

FIG. 7 is a schematic plan view of an embodiment;

FIG. 8 is a magnified view schematically showing at least a portion of the cross-section of a display apparatus according to an embodiment;

FIG. 9 is an enlarged schematic view of at least a portion of the cross-section of the display apparatus of FIG. 8; and

FIGS. 10 through 17 are cross-sectional views schematically illustrating a method of manufacturing a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

One or more embodiments will be described below in more detail with reference to the accompanying drawings. Those components that are the same as or are in correspondence with each other are rendered the same reference numeral regardless of the figure number, and redundant explanations are omitted.

It will be understood that although the terms “first,” “second,” etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. That is, for example, intervening layers, regions, or components may be present.

Sizes of elements in the drawings may be exaggerated or reduced for convenience of explanation. For example, since sizes and thicknesses of components in the drawings are arbitrarily illustrated for convenience of explanation, embodiments are not limited thereto.

When a certain embodiment may be implemented differently, a specific process order may be performed differently from the described order. For example, two consecutively described processes may be performed substantially at the same time or performed in an order opposite to the described order.

In the present specification, “A and/or B” represents A or B, or A and B. The expression “at least one of A and B” indicates only A, only B, both A and B, or variations thereof.

It will also be understood that when a layer, region, or component is referred to as being “connected” or “coupled” to another layer, region, or component, it can be directly connected or coupled to the other layer, region, or/and component or intervening layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

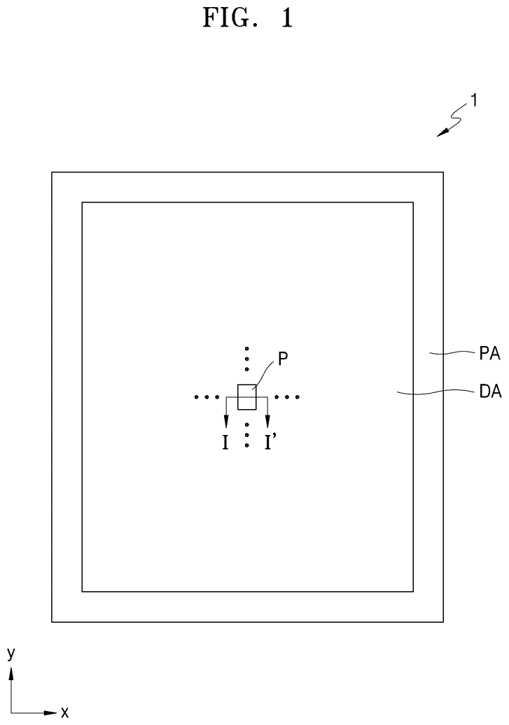

FIG. 1 is a schematic plan view of a display apparatus 1 according to an embodiment.

Referring to FIG. 1, the display apparatus 1 may include a display area DA and a peripheral area PA around the display area DA. The display area DA may display an image through pixels P arranged in the display area DA. The peripheral area PA is a non-display area that is disposed around the display area DA and does not display an image, and may surround the entirety of the display area DA. A driver or the like for providing an electrical signal or power to the display area DA may be arranged in the peripheral area PA. A pad that is an area where an electronic device or a printed circuit board (PCB) may be electrically connected may be disposed in the peripheral area PA.

According to an embodiment, FIG. 1 illustrates that the display area DA is a polygon (e.g., a quadrangle) of which a length in an x direction is less than that in a y direction. However, the disclosure is not limited thereto. According to another embodiment, the display area DA may be a polygon (e.g., a quadrangle) of which a length in a y direction is less than that in an x direction. Although FIG. 1 illustrates that the display area DA has a shape of approximately a rectangle, the disclosure is not limited thereto. According to another embodiment, the display area DA may have various shapes such as an N-gon (where N is a natural number equal to or greater than 3), a circle, or an ellipse. In FIG. 1, each of the corners of the display area DA includes a vertex where straight lines meet each other. However, in another embodiment, the display area DA may be a polygon with rounded corners.

A case in which the display apparatus 1 is an electronic device that is a smartphone will now be described for convenience of description, but the display apparatus 1 of the disclosure is not limited thereto. The display apparatus 1 is applicable to not only portable electronic apparatuses, such as mobile phones, smartphones, tablet personal computers (PCs), mobile communication terminals, electronic notebooks, electronic books, portable multimedia players (PMPs), navigation devices, and ultra mobile PCs (UMPCs) but also various products, such as televisions, notebooks, monitors, advertisement panels, and Internet of things (IoT) devices. The display apparatus 1 according to an embodiment is also applicable to wearable devices, such as smart watches, watch phones, glasses-type displays, and head mounted displays (HMDs). The display apparatus 1 according to an embodiment is also applicable to dashboards of automobiles, center information displays (CIDs) of the center fasciae or dashboards of automobiles, room mirror displays that replace the side mirrors of automobiles, and displays arranged on the rear sides of front seats to serve as entertainment devices for back seat passengers of automobiles.

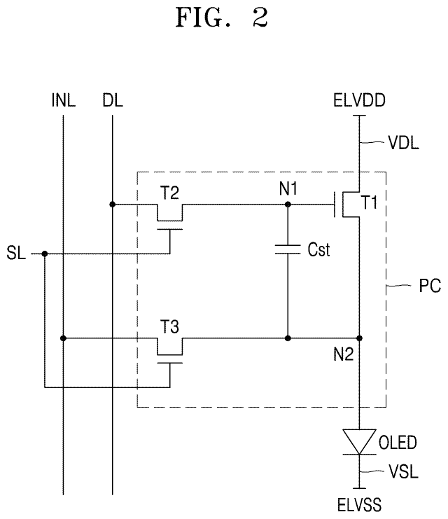

FIG. 2 is a schematic equivalent circuit diagram of one subpixel circuit included in a display apparatus according to an embodiment.

Referring to FIG. 2, a subpixel circuit PC may include a plurality of transistors and at least one capacitor. According to an embodiment, the subpixel circuit PC may include a first thin-film transistor T1, a second thin-film transistor T2, a third thin-film transistor T3, and a storage capacitor Cst.

Each of the first thin-film transistor T1, the second thin-film transistor T2, and the third thin-film transistor T3 may be an oxide semiconductor thin-film transistor including a semiconductor layer composed of an oxide semiconductor, or a silicon semiconductor thin-film transistor including a semiconductor layer composed of polysilicon. Each thin-film transistor may have a first electrode and a second electrode. Depending on the type of the thin film transistor, the first electrode may be one of a source electrode and a drain electrode, and the second electrode may be the other of the source electrode and the drain electrode. Each thin-film transistor may also include a gate electrode.

The first thin-film transistor T1 may be a driving thin-film transistor. The first electrode of the first thin-film transistor T1 may be connected to a driving voltage line VDL that supplies a driving power voltage ELVDD, and the second electrode thereof may be connected to a pixel electrode of the organic light-emitting diode OLED. A gate electrode of the first thin-film transistor T1 may be connected to a first node N1. The first thin-film transistor T1 may control a current amount flowing through the organic light-emitting diode OLED from the driving power supply voltage ELVDD in accordance with a voltage of the first node N1.

The second thin-film transistor T2 may be a switching thin-film transistor. A first electrode of the second thin-film transistor T2 may be connected to a data line DL, and a second electrode thereof may be connected to the first node N1. A gate electrode of the second thin-film transistor T2 may be connected to a scan line SL. The second thin-film transistor T2 may be turned on when a scan signal is supplied to the scan line SL, and may electrically connect the data line DL to the first node N1.

The third thin-film transistor T3 may be an initialization thin-film transistor and/or a sensing thin-film transistor. A first electrode of the third thin-film transistor T3 may be connected to a second node N2, and a source electrode thereof may be connected to an initializing voltage line INL. A gate electrode of the third thin-film transistor T3 may be connected to the scan line SL.

The third thin-film transistor T3 may be turned on when a scan signal is supplied to the scan line SL, and may electrically connect the initializing voltage line INL to the second node N2. According to some embodiments, the third thin-film transistor T3 may be turned on according to a signal received through the scan line SL to initialize the pixel electrode of the organic light-emitting diode OLED by using an initializing voltage from the initializing voltage line INL.

According to some embodiments, the third thin-film transistor T3 may be turned on when the scan signal is supplied to the scan line SL, and may sense property information of the organic light-emitting diode OLED. The third thin-film transistor T3 may include both a function as the above-described initialization thin-film transistor and a function as the above-described sensing thin-film transistor, or may include one of the two functions. An initialization operation and a sensing operation of the third thin-film transistor T3 may be individually conducted or may be simultaneously conducted. When the third thin-film transistor T3 has a function as a sensing thin-film transistor, the initializing voltage line INL may be referred to as a sensing line.

The storage capacitor Cst may be connected between the first node N1 and the second node N2. For example, a first capacitor plate of the storage capacitor Cst may be connected to the gate electrode of the first thin-film transistor T1, and a second capacitor plate of the storage capacitor Cst may be connected to the pixel electrode of the organic light-emitting diode OLED.

An opposite electrode of the organic light-emitting diode OLED may be connected to a common voltage line VSL providing a common power supply voltage ELVSS.

Although a case where the pixel circuit PC includes three thin-film transistors and one storage capacitor is illustrated in FIG. 2, the disclosure is not limited thereto. According to another embodiment, the number of thin-film transistors or the number of storage capacitors may vary according to a design of the subpixel circuit PC.

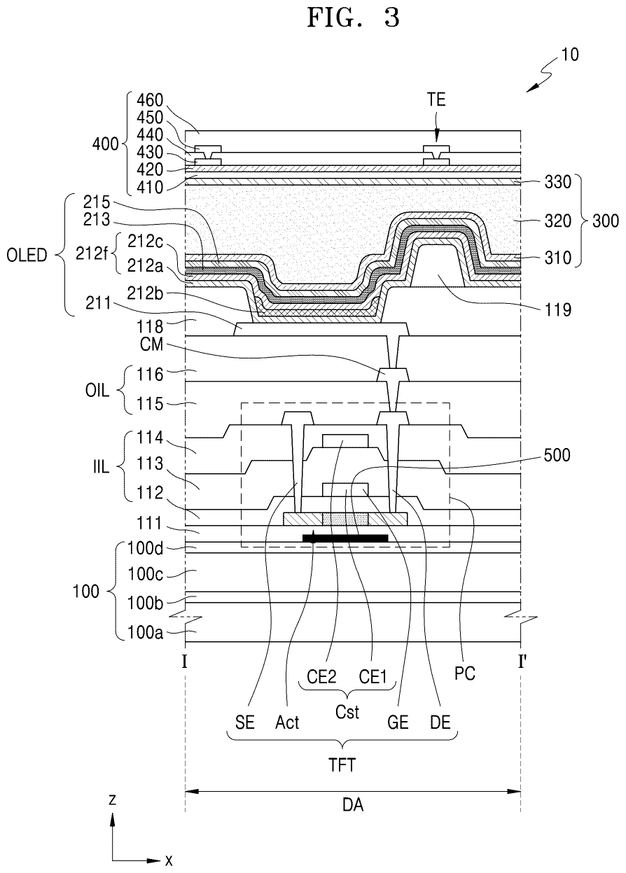

FIG. 3 is a schematic cross-sectional view of a portion of a display apparatus. In detail, FIG. 3 is a schematic cross-sectional view of the display apparatus 1 of FIG. 1 taken along line I-I′.

Referring to FIG. 3, the display panel 10 may include a substrate 100, an inorganic insulating layer IIL, an organic insulating layer OIL, a subpixel circuit PC, a connection electrode CM, an organic light-emitting diode OLED, a pixel defining layer 118, a spacer 119, and an encapsulation layer 300. In other words, the substrate 100, the inorganic insulating layer IIL, the organic insulating layer OIL, the subpixel circuit PC, the connection electrode CM, the organic light-emitting diode OLED, the pixel defining layer 118, the spacer 119, and the encapsulation layer 300 may be arranged in the display area DA of the display panel 10.

The substrate 100 may include a first base layer 100a, a first barrier layer 100b, a second base layer 100c, and a second barrier layer 100d. According to an embodiment, the first base layer 100a, the first barrier layer 100b, the second base layer 100c, and the second barrier layer 100d may be sequentially stacked on one another in a thickness direction of the substrate 100.

At least one of the first base layer 100a and the second base layer 100c may include polymer resin such as polyethersulfone, polyacrylate, polyetherimide, polyethylene naphthalate, polyethylene terephthalate, polyphenylene sulfide, polyimide, polycarbonate, cellulose triacetate, or cellulose acetate propionate.

Each of the first barrier layer 100b and the second barrier layer 100d, which is a barrier layer for preventing penetration of an external foreign material, may have a single or multi-layer structure including an inorganic material such as silicon nitride (SiNx), silicon oxide (SiO₂), and/or silicon oxynitride (SiON).

A lower metal layer 500 may be arranged on the substrate 100. The lower metal layer 500 may be disposed to overlap a semiconductor layer Act. According to some embodiments, a constant voltage or a signal may be applied to the lower metal layer 500. The lower metal layer 500 may include molybdenum (Mo) or titanium (Ti). The lower metal layer 500 may be disposed to overlap the semiconductor layer Act, so that characteristics of a thin-film transistor TFT may be improved.

A buffer layer 111 may be arranged on the substrate 100 and the lower metal layer 500. The buffer layer 111 may include an inorganic insulating material, such as silicon nitride (SiNx), silicon oxynitride (SiON), or silicon oxide (SiO₂), and may have a single-layer or multi-layer structure including the aforementioned inorganic insulating material.

The inorganic insulating layer IIL may be arranged on the buffer layer 111. The inorganic insulating layer IIL may include a first gate insulating layer 112, a second gate insulating layer 113, and an interlayer insulating layer 114.

The subpixel circuit PC may be arranged in the display area DA. The subpixel circuit PC may include the thin-film transistor TFT and the storage capacitor Cst. The thin-film transistor TFT may include the semiconductor layer Act, a gate electrode GE, a source electrode SE, and a drain electrode DE.

The semiconductor layer Act may be arranged on the buffer layer 111. The semiconductor layer Act may include polysilicon. Alternatively, the semiconductor layer Act may include amorphous silicon, an oxide semiconductor, or an organic semiconductor.

The semiconductor layer Act may include a channel region, and a source region and a drain region respectively arranged on both sides of the channel region.

The gate electrode GE may be arranged on the semiconductor layer Act. The gate electrode GE may overlap the channel region. The gate electrode GE may include a low resistance metal material. The gate electrode GE may include a conductive material including molybdenum (Mo), aluminum (Al), copper (Cu), and titanium (Ti), and may be formed as a multi-layer or single layer including the aforementioned materials.

The first gate insulating layer 112 may be between the semiconductor layer Act and the gate electrode GE. The first gate insulating layer 112 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The second gate insulating layer 113 may be arranged on the gate electrode GE. The second gate insulating layer 113 may be included to cover the gate electrode GE. The second gate insulating layer 113 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

A second capacitor plate CE2 of the storage capacitor Cst may be disposed on the second gate insulating layer 113. The second capacitor plate CE2 may overlap the gate electrode GE located therebelow. In this case, the gate electrode GE and the second capacitor plate CE2 overlapping each other with the second gate insulating layer 113 therebetween may constitute the storage capacitor Cst. In other words, the gate electrode GE may function as a first capacitor plate CE1 of the storage capacitor Cst.

As described above, the storage capacitor Cst and the thin-film transistor TFT may overlap each other. However, the disclosure is not limited thereto. For example, the storage capacitor Cst and the thin-film transistor TFT may not overlap each other. In other words, the first capacitor plate CE1 of the storage capacitor Cst, which is a separate component from the gate electrode GE of the thin-film transistor TFT, may be included apart from the gate electrode GE of the thin-film transistor TFT.

The second capacitor plate CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multi-layer including the aforementioned materials.

The interlayer insulating layer 114 may be disposed on the second capacitor plate CE2. The interlayer insulating layer 114 may cover the second capacitor plate CE2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO), or the like. The interlayer insulating layer 114 may be a single layer or multi-layer including the aforementioned inorganic insulating materials.

The drain electrode DE and the source electrode SE may be located on the interlayer insulating layer 114. The drain electrode DE and the source electrode SE may each be connected to the semiconductor layer Act via respective contact holes included in the first gate insulating layer 112, the second gate insulating layer 113, and the third gate insulating layer 114. The drain electrodes DE and the source electrode SE may include a highly conductive material. Each of the source electrode SE and the drain electrode DE may include a conductive material including Mo, Al, Cu, and Ti, and may be a multi-layer or single layer including the aforementioned materials. For example, the drain electrodes DE and the source electrode SE may have a multi-layer structure of Ti/Al/Ti.

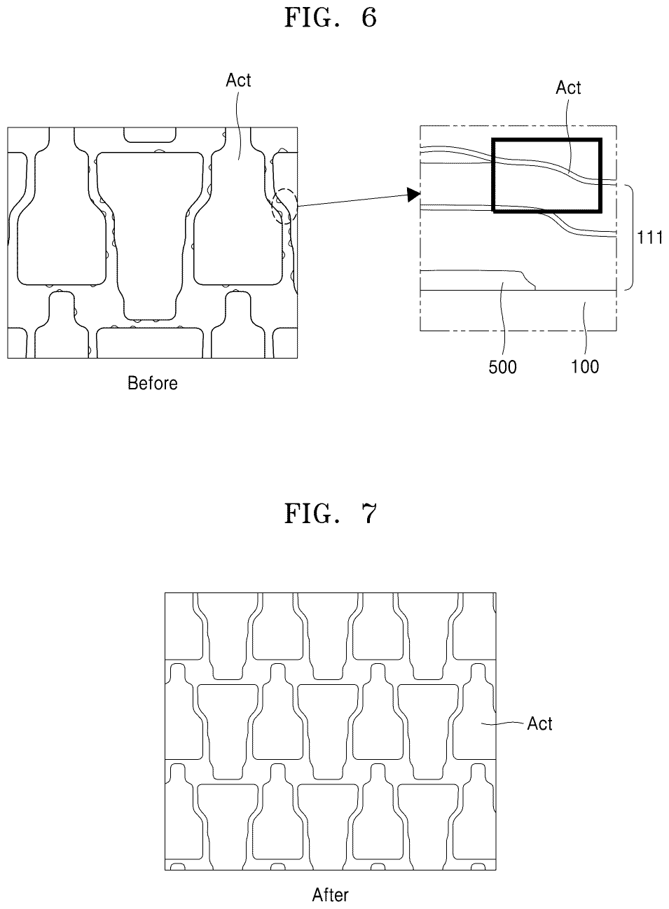

The organic insulating layer OIL may be disposed on the inorganic insulating layer IIL. The organic insulating layer OIL may include a first organic insulating layer 115 and a second organic insulating layer 116. Although two organic insulating layers OIL are provided in FIG. 6, the disclosure is not limited thereto. Three or four organic insulating layers OIL may be included.

The first organic insulating layer 115 may cover the drain electrode DE and the source electrode SE. The first organic insulating layer 115 may include an organic insulating material, such as a commercial polymer (such as PMMA or PS), a polymer derivative having a phenol-based group, an acrylic polymer, an imide-based polymer, an acryl ether-based polymer, an amide-based polymer, a fluorine-based polymer, a p-xylene-based polymer, a vinyl alcohol-based polymer, or a blend thereof.

The connection electrode CM may be disposed on the first organic insulating layer 115. In this case, the connection electrode CM may be connected to the drain electrode DE or the source electrode SE through the contact hole of the first organic insulating layer 115. The connection electrode CM may include a highly conductive material. The connection electrode CM may include a conductive material including Mo, Al, Cu, and Ti, and may be formed as a multi-layer or single layer including the aforementioned materials. For example, the connection electrode CM may have a multi-layer structure of Ti/Al/Ti.

The second organic insulating layer 116 may be arranged on the connection electrode CM. The second organic insulating layer 116 may cover the connection electrode CM. The second organic insulating layer 116 may include the same material as that included in the first organic insulating layer 115, or may include a different material from that included in the first organic insulating layer 115.

A light-emitting diode may be disposed on the second organic insulating layer 116. For example, the organic light-emitting diode OLED may be arranged on the second organic insulating layer 116. Alternatively, although not shown in the drawings, an inorganic light-emitting diode or the like may be disposed on the second organic insulating layer 116.

The organic light-emitting diode OLED may emit red light, green light, or blue light, or may emit red light, green light, blue light, or white light. The organic light-emitting diode OLED may include a first electrode 211, an emission layer 212b, a functional layer 212f, a second electrode 213, and a capping layer 215. The first electrode 211 may be a pixel electrode (e.g., an anode) of the organic light-emitting diode OLED, and the second electrode 213 may be an opposite electrode (e.g., a cathode) of the organic light-emitting diode OLED.

The first electrode 211 may be arranged on the second organic insulating layer 116. The first electrode 211 may be electrically connected to the connection electrode CM through a contact hole defined in the second organic insulating layer 116. The first electrode 211 may include conductive oxide such as indium tin oxide (ITO), indium zinc oxide (IZO), zinc oxide (ZnO), indium oxide (In₂O₃), indium gallium oxide (IGO), or aluminum zinc oxide (AZO). According to an embodiment, the first electrode 211 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound of these materials. According to an embodiment, the first electrode 211 may further include a film formed of ITO, IZO, ZnO, or In₂O₃ above/below the reflective layer. For example, the first electrode 211 may have a multi-layered structure of ITO/Ag/ITO.

A pixel defining layer 118 having an opening through which at least a portion of the first electrode 211 is exposed may be arranged on the first electrode 211. An emission area of light emitted by the organic light-emitting diode OLED may be defined by the opening defined in the pixel defining layer 118. For example, a width of the opening may correspond to a width of the emission area.

The pixel defining layer 118 may include an organic insulating material. Alternatively, the pixel defining layer 118 may include an inorganic insulating material such as silicon nitride, silicon oxynitride, or silicon oxide. Alternatively, the pixel defining layer 118 may include an organic insulating material and an inorganic insulating material. According to an embodiment, the pixel defining layer 118 may include a light shielding material. The light shielding material may include carbon black, carbon nanotubes, resin or paste including a black pigment, metal particles (e.g., nickel, aluminum, molybdenum, and an alloy thereof), metal oxide particles (e.g., a chromium oxide), or metal nitride particles (e.g., a chromium nitride). When the pixel defining layer 118 includes the light shielding material, external light reflection due to metal structures arranged under the pixel defining layer 118 may be reduced.

A spacer 119 may be located on the pixel defining layer 118. The spacer 119 may include an organic insulating material such as polyimide. Alternatively, the spacer 119 may include an inorganic insulating material such as silicon nitride (SiNₓ) or silicon oxide (SiO₂), or may include an inorganic insulating material and an organic insulating material.

According to an embodiment, the spacer 119 may include the same material as that included in the pixel defining layer 118. In this case, the pixel defining layer 118 and the spacer 119 may be simultaneously (or concurrently) formed during a mask process that uses a half-tone mask. Alternatively, the spacer 119 may include a material different from that included in the pixel defining layer 118.

The emission layer 212b may be disposed in the opening of the pixel defining layer 118. The emission layer 212b may include a low molecular weight or high molecular weight organic material that emits light of a certain color.

The functional layer 212f may include a first functional layer 212a and a second functional layer 212c. The first functional layer 212a may be disposed between the first electrode 211 and the emission layer 212b, and the second functional layer 212c may be disposed between the emission layer 212b and the second electrode 213. However, at least one of the first functional layer 212a or the second functional layer 212c may be omitted. A case where the first functional layer 212a and the second functional layer 212c are individually arranged will now be focused on and described in detail.

The first functional layer 212a may include a hole transport layer (HTL) and/or a hole injection layer (HIL). The second functional layer 212c may include an electron transport layer (ETL) and/or an electron injection layer (EIL). The first functional layer 212a and/or the second functional layer 212c may be a common layer formed to entirely cover the substrate 100, similar to the second electrode 213 to be described later.

The second electrode 213 may be arranged on the functional layer 212f. The second electrode 213 may include a conductive material having a low work function. For example, the second electrode 213 may include a (semi) transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. Alternatively, the second electrode 213 may further include a layer, such as ITO, IZO, ZnO, or In₂O₃, on the (semi) transparent layer including any of the above-described materials.

According to an embodiment, the capping layer 215 may be disposed on the second electrode 213. The capping layer 215 may include lithium fluoride (LiF), an inorganic material, or/and an organic material.

The encapsulation layer 300 may be arranged on the organic light-emitting diode OLED. The encapsulation layer 300 may cover the organic light-emitting diode OLED. The encapsulation layer 300 may be disposed on the second electrode 213 and/or the capping layer 215. According to an embodiment, the encapsulation layer 300 may include at least one inorganic encapsulation layer and at least one organic encapsulation layer. In FIG. 3, the encapsulation layer 300 includes a first inorganic encapsulation layer 310, an organic encapsulation layer 320, and a second inorganic encapsulation layer 330 sequentially stacked on one another.

The first inorganic encapsulation layer 310 and the second inorganic encapsulation layer 330 may include at least one inorganic material, such as aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may be a single layer or multi-layer including the aforementioned materials. The organic encapsulation layer 320 may include a polymer-based material. Examples of the polymer-based material may include an acrylic resin, an epoxy-based resin, polyimide, and polyethylene. According to an embodiment, the organic encapsulation layer 320 may include acrylate.

An input sensing layer 400 may be arranged on the encapsulation layer 300. The input sensing layer 400 may include a first touch insulating layer 410, a second touch insulating layer 420, a first conductive layer 430, a third touch insulating layer 440, a second conductive layer 450, and a planarization layer 460.

According to an embodiment, the first touch insulating layer 410 may be arranged on the second inorganic insulating layer 330, and the second touch insulating layer 420 may be arranged on the first touch insulating layer 410. According to an embodiment, each of the first touch insulating layer 410 and the second touch insulating layer 420 may include an inorganic insulating material and/or an organic insulating material. For example, each of the first touch insulating layer 410 and the second touch insulating layer 420 may include an inorganic insulating material, such as silicon oxide, silicon nitride, and/or silicon oxynitride.

According to an embodiment, at least one of the first touch insulating layer 410 and the second touch insulating layer 420 may be omitted. For example, the first touch insulating layer 410 may be omitted. In this case, the second touch insulating layer 420 may be arranged on the second inorganic insulating layer 330, and the first conductive layer 430 may be arranged on the second touch insulating layer 420.

The first conductive layer 430 may be arranged on the second touch insulating layer 420, and the third touch insulating layer 440 may be arranged on the first conductive layer 430. According to an embodiment, the third touch insulating layer 440 may include an inorganic insulating material and/or an organic insulating material. For example, the third touch insulating layer 440 may include an inorganic insulating material, such as silicon oxide, silicon nitride, and/or silicon oxynitride.

The second conductive layer 450 may be arranged on the third touch insulating layer 440. A touch electrode TE of the input sensing layer 40 may have a structure in which the first conductive layer 430 and the second conductive layer 450 are connected to each other. Alternatively, the touch electrode TE may be formed on one of the first conductive layer 430 and the second conductive layer 450, and may include a metal line in the one of the first conductive layer 430 and the second conductive layer 450. The first conductive layer 430 and the second conductive layer 450 may each include at least one of aluminum (Al), copper (Cu), titanium (Ti), molybdenum (Mo), and indium tin oxide (ITO), and may be implemented as a single layer or multiple layers including the aforementioned materials. For example, the first conductive layer 430 and the second conductive layer 450 may each have a three-layered structure of Ti layer/Al layer/Ti layer.

According to an embodiment, the planarization layer 460 may cover the second conductive layer 450. The planarization layer 460 may include an organic insulating material.

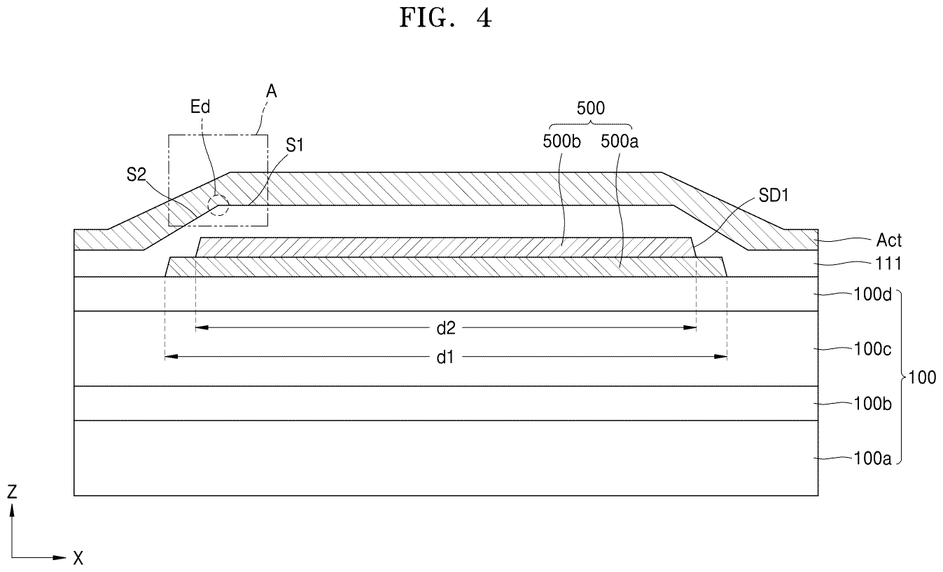

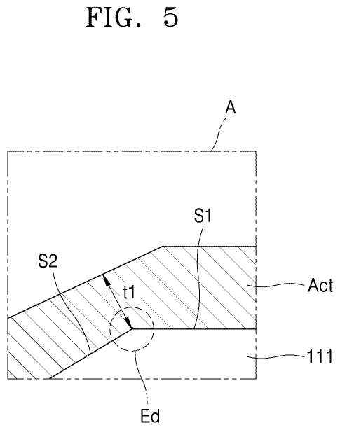

FIG. 4 is a magnified cross-sectional view schematically showing at least a portion of the cross-section of a display apparatus according to an embodiment. In detail, FIG. 4 is an enlarged cross-sectional view schematically showing the substrate 100, the buffer layer 111, the lower metal layer 500, and the semiconductor layer Act. FIG. 5 is a schematic enlarged cross-sectional view of at least a portion of the cross-section of the display apparatus of FIG. 4. In detail, FIG. 5 is a schematic enlarged cross-sectional view of a region A of FIG. 4. FIG. 6 schematically shows a plan view and a cross-sectional view when the lower metal layer 500 is provided as a single layer.

Referring to FIG. 4, the lower metal layer 500 disposed on the substrate 100 may include a first lower metal layer 500a and a second lower metal layer 500b. The second lower metal layer 500b may be arranged over the first lower metal layer 500a. The second lower metal layer 500b may be arranged to contact at least a portion of an upper surface of the first lower metal layer 500a. The second lower metal layer 500b may be arranged to have a step difference SD1 with respect to an edge portion of the first second lower metal layer 500a. In other words, an edge portion of the second lower metal layer 500b and the edge portion of the first second lower metal layer 500a may be stepped. The longest length d1 of the first lower metal layer 500a in a first direction (e.g., an x direction or an −x direction) may be greater than the longest length d2 of the second lower metal layer 500b in the first direction (e.g., the x direction or the −x direction).

The first lower metal layer 500a and the second lower metal layer 500b may include different materials from each other. According to an embodiment, when the first lower metal layer 500a includes titanium (Ti), the second lower metal layer 500b may include molybdenum (Mo). According to another embodiment, when the first lower metal layer 500a includes molybdenum (Mo), the second lower metal layer 500b may include titanium (Ti).

A lateral surface of the first lower metal layer 500a may be provided as an inclined surface. A lateral surface of the second lower metal layer 500b may be provided as an inclined surface. The lateral surface of the first lower metal layer 500a and the lateral surface of the second lower metal layer 500b may each be included in a positive taper shape.

The buffer layer 111 may be arranged on the first lower metal layer 500a and the second lower metal layer 500b. Because the lateral surface of the first lower metal layer 500a and the lateral surface of the second lower metal layer 500b are provided as inclined surfaces and in positive taper shapes, a lateral surface of the buffer layer 111 disposed on the first lower metal layer 500a and the second lower metal layer 500b may also be provided as an inclined surface.

According to an embodiment, the semiconductor layer Act may be arranged on the buffer layer 111. Because the lateral surface of the buffer layer 111 is provided as an inclined surface, a lateral surface of the semiconductor layer Act at the buffer layer 111 may also be provided as an inclined surface.

In a process of forming the semiconductor layer Act on the buffer layer 111, a semiconductor layer-forming material may be disposed on the buffer layer 111 and then irradiated with a solid laser in a UV wavelength range to crystalize amorphous silicon contained in the semiconductor layer-forming material into polycrystalline silicon. When a solid laser is radiated several times to the semiconductor layer-forming material, thermal energy needs to be released to the top and bottom of the semiconductor layer-forming material, but thermal conductivity of a second base layer 100c included in the substrate 100 is very low. Thus, a temperature may increase at an interface between the second base layer 100c and the second barrier layer 100d disposed on the second base layer 100c. Thermal energy accumulated due to the increase in the temperature at the interface between the second base layer 100c and the second barrier layer 100d increases a temperature of the buffer layer 111 disposed on the second barrier layer 100d, and the buffer layer 111 contains a lot of hydrogen (H₂), so hydrogen (H₂) may diffuse in a direction where heat is high, that is, in a direction from the buffer layer 111 to the semiconductor layer Act. Hydrogen (H₂) diffused into the semiconductor layer Act may increase a concentration of the hydrogen (H₂) inside the semiconductor layer Act, and may cause membrane rupture of the semiconductor layer Act due to laser radiation.

Referring to FIGS. 4 and 6, the plan view on the left side of FIG. 6 schematically shows occurrence of membrane bursting at an edge portion of the semiconductor layer Act due to hydrogen (H₂). In addition, the cross-sectional view on the right side of FIG. 6 shows that a thickness t1 of the semiconductor layer Act at an edge Ed where a top surface S1 of the buffer layer 111 farthest from the substrate 100 and a lateral surface S2 of the buffer layer 111 meet each other is less than the other portions.

In a process of forming a semiconductor layer by disposing and crystallizing a semiconductor layer-forming material on the buffer layer 111, the semiconductor layer-forming material may be disposed and crystallized in a direction of lowering the surface energy of the semiconductor layer-forming material. When the lower metal layer 500 is provided as a single layer, an inclination angle between the upper surface of the substrate 100 and the edge of an upper portion of the lower metal layer 500 may be greater than when the lower metal layer 500 is provided as multiple layers. When the lower metal layer 500 is provided as a single layer, an inclination angle of the lateral surface of the buffer layer 111 may be greater than when the lower metal layer 500 is provided as multiple layers. Because the semiconductor layer Act is formed on the buffer layer 111 in a direction for lowering the surface energy, when the inclination angle of the lateral surface of the buffer layer 111 is large, the thickness t1 of the semiconductor layer Act at the edge Ed where the top surface S1 of the buffer layer 111 farthest from the substrate 100 and the lateral surface S2 of the buffer layer 111 meet each other may be less than the other portions.

When the lower metal layer 500 is provided as a single layer, the thickness t1 of at least a portion of the semiconductor layer Act, namely, a semiconductor layer Act at the edge Ed of the buffer layer 111, may be less than the other portions, and, as described above, membrane rupture of the semiconductor layer Act due to hydrogen (H₂) diffused into the semiconductor layer Act due to the thermal energy accumulated due to laser radiation may easily occur, causing defects.

Referring to FIGS. 4 and 5, according to an embodiment, the thickness t1 of the semiconductor layer Act at the edge Ed where the top surface S1 of the buffer layer 111 farthest from the substrate 100 and the lateral surface S2 of the buffer layer 111 meet each other may be about 320 angstroms (Å) to about 480 Å. In general, a thickness of the semiconductor layer Act disposed parallel to the substrate 100 may be about 400 Å to about 600 Å. The thickness t1 of the semiconductor layer Act at the edge Ed where the top surface S1 of the buffer layer 111 farthest from the substrate 100 and the lateral surface S2 of the buffer layer 111 meet each other may be 80% to 100% of the thickness of the semiconductor layer Act disposed parallel to the substrate 100. When the thickness t1 of the semiconductor layer Act at the edge Ed where the top surface S1 of the buffer layer 111 farthest from the substrate 100 and the lateral surface S2 of the buffer layer 111 meet each other is less than about 320 Å, membrane rupture of the semiconductor layer Act due to hydrogen (H₂) diffused into the semiconductor layer Act in the buffer layer 111 due to the thermal energy accumulated due to laser radiation occurs, causing defects. When the thickness t1 of the semiconductor layer Act at the edge Ed where the top surface S1 of the buffer layer 111 farthest from the substrate 100 and the lateral surface S2 of the buffer layer 111 meet each other exceeds about 480 Å, the time required for a manufacturing process of a display apparatus may increase, and the characteristics of a semiconductor may not be revealed.

FIG. 7 is a schematic plan view of an embodiment. Referring to FIGS. 4 and 7, according to an embodiment, when the thickness t1 of the semiconductor layer Act at the edge Ed where the top surface S1 of the buffer layer 111 farthest from the substrate 100 and the lateral surface S2 of the buffer layer 111 meet each other is about 320 Å to about 480 Å, even when hydrogen (H₂) is diffused into the semiconductor layer Act in the buffer layer 111 due to the thermal energy accumulated due to laser radiation, it may be confirmed that membrane rupture due to of the semiconductor layer Act does not occur in the semiconductor layer Act.

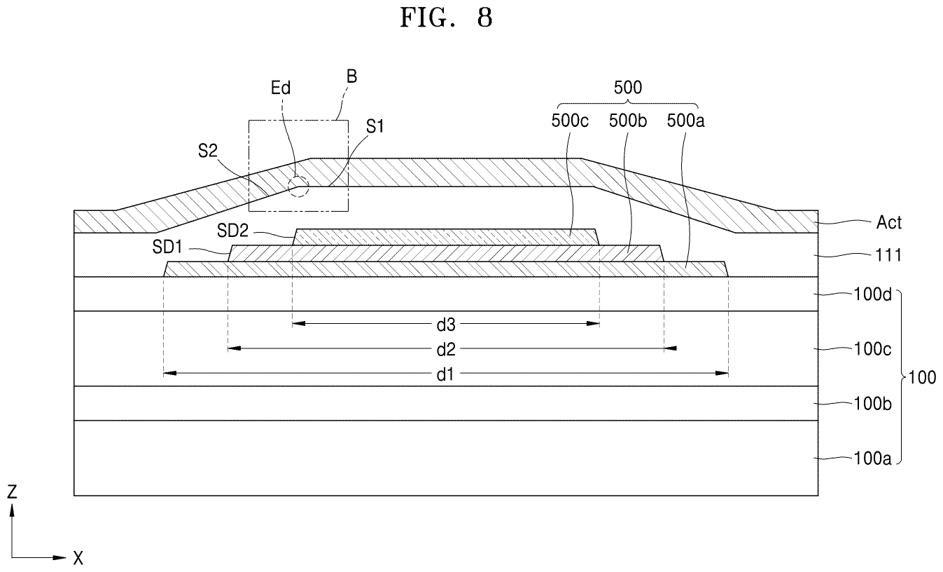

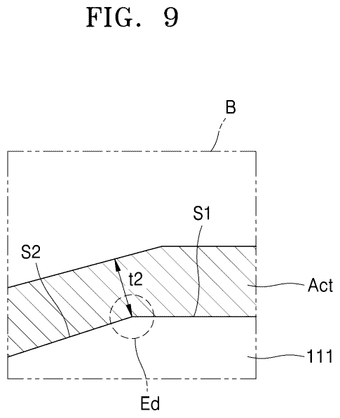

FIG. 8 is a magnified cross-sectional view schematically showing at least a portion of the cross-section of a display apparatus according to an embodiment. In detail, FIG. 8 is an enlarged cross-sectional view schematically showing a substrate 100, a buffer layer 111, a lower metal layer 500, and a semiconductor layer Act. FIG. 9 is a schematic enlarged cross-sectional view of at least a portion of the cross-section of the display apparatus of FIG. 8. In detail, FIG. 9 is a schematic enlarged cross-sectional view of a region B of FIG. 8.

Referring to FIG. 8, the lower metal layer 500 disposed on the substrate 100 may include a first lower metal layer 500a, a second lower metal layer 500b, and a third lower metal layer 500c. The second lower metal layer 500b may be at the first lower metal layer 500a, and the third lower metal layer 500c may be at the second lower metal layer 500b. The first lower metal layer 500a may be disposed at the bottom, the third lower metal layer 500c may be disposed at the top, and the second lower metal layer 500b may be disposed between the first lower metal layer 500a and the third lower metal layer 500c.

The second lower metal layer 500b may be arranged to have a step difference SD1 with respect to an edge portion of the first lower metal layer 500a. In other words, an edge portion of the second lower metal layer 500b and an edge portion of the first lower metal layer 500a may be stepped. The longest length d1 of the first lower metal layer 500a in a first direction (e.g., an x direction or an −x direction) may be greater than the longest length d2 of the second lower metal layer 500b in the first direction (e.g., the x direction or the −x direction).

The third lower metal layer 500c may be arranged to have a step difference SD2 with respect to the edge portion of the second lower metal layer 500b. In other words, the edge portion of the third lower metal layer 500c and the edge portion of the second lower metal layer 500b may be stepped. The longest length d2 of the second lower metal layer 500b in a first direction (e.g., an x direction or an −x direction) may be greater than the longest length d3 of the third lower metal layer 500c in the first direction (e.g., the x direction or the −x direction).

The first lower metal layer 500a and the second lower metal layer 500b may include different materials from each other. The second lower metal layer 500b and the third lower metal layer 500c may include different materials from each other. According to an embodiment, when the first lower metal layer 500a includes titanium (Ti), the second lower metal layer 500b may include molybdenum (Mo), and the third lower metal layer 500c may include titanium (Ti). According to another embodiment, when the first lower metal layer 500a includes molybdenum (Mo), the second lower metal layer 500b may include titanium (Ti), and the third lower metal layer 500c may include molybdenum (Mo).

A lateral surface of the first lower metal layer 500a, a lateral surface of the second lower metal layer 500b, and a lateral surface of the third lower metal layer 500c may be provided as inclined surfaces. The lateral surface of the first lower metal layer 500a, the lateral surface of the second lower metal layer 500b, and the lateral surface of the third lower metal layer 500c may be provided in positive taper shapes.

The buffer layer 111 may be arranged on the first lower metal layer 500a, the second lower metal layer 500b, and the third lower metal layer 500c. Because the lateral surface of the first lower metal layer 500a, the lateral surface of the second lower metal layer 500b, and the lateral surface of the third lower metal layer 500c are provided as inclined surfaces and in positive taper shapes, a lateral surface of the buffer layer 111 disposed on the first lower metal layer 500a, the second lower metal layer 500b, and the third lower metal layer 500c may also be provided as an inclined surface.

According to an embodiment, the semiconductor layer Act may be arranged on the buffer layer 111. Because the lateral surface of the buffer layer 111 is provided as an inclined surface, a lateral surface of the semiconductor layer Act disposed on the buffer layer 111 may also be provided as an inclined surface.

In a process of forming the semiconductor layer Act by disposing and crystallizing a semiconductor layer-forming material on the buffer layer 111, the semiconductor layer-forming material may be disposed and crystallized in a direction of lowering the surface energy of the semiconductor layer-forming material. When the lower metal layer 500 is provided as a single layer, an inclination angle between the upper surface of the substrate 100 and the edge of an upper portion of the lower metal layer 500 may be greater than when the lower metal layer 500 is provided as multiple layers. When the lower metal layer 500 is provided as a single layer, an inclination angle of the lateral surface of the buffer layer 111 may be greater than when the lower metal layer 500 is provided as multiple layers. Because the semiconductor layer Act is formed on the buffer layer 111 in a direction for lowering the surface energy, when the inclination angle of the lateral surface of the buffer layer 111 is large, a thickness t2 of the semiconductor layer Act at the edge Ed where a top surface S1 of the buffer layer 111 farthest from the substrate 100 and a lateral surface S2 of the buffer layer 111 meet each other may be less than the other portions.

When the lower metal layer 500 is provided as a single layer, the thickness t2 of at least a portion of the semiconductor layer Act, namely, a semiconductor layer Act at the edge Ed of the buffer layer 111, may be less than the other portions, and, as described above, membrane rupture of the semiconductor layer Act due to hydrogen (H₂) diffused into the semiconductor layer Act due to the thermal energy accumulated by a laser may be generated, causing defects.

Referring to FIGS. 8 and 9, the thickness t2 of the semiconductor layer Act at the edge Ed where the top surface S1 of the buffer layer 111 farthest from the substrate 100 and the lateral surface S2 of the buffer layer 111 meet each other may be about 320 Å to about 480 Å. When the thickness t2 of the semiconductor layer Act at the edge Ed where the top surface S1 of the buffer layer 111 farthest from the substrate 100 and the lateral surface S2 of the buffer layer 111 meet each other is less than about 320 Å, membrane rupture of the semiconductor layer Act due to hydrogen (H₂) diffused into the semiconductor layer Act in the buffer layer 111 due to the thermal energy accumulated due to laser radiation occurs, causing defects. When the thickness t2 of the semiconductor layer Act at the edge Ed where the top surface S1 of the buffer layer 111 farthest from the substrate 100 and the lateral surface S2 of the buffer layer 111 meet each other exceeds about 480 Å, the time required for a manufacturing process of a display apparatus may increase, and the characteristics of a semiconductor may not be revealed.

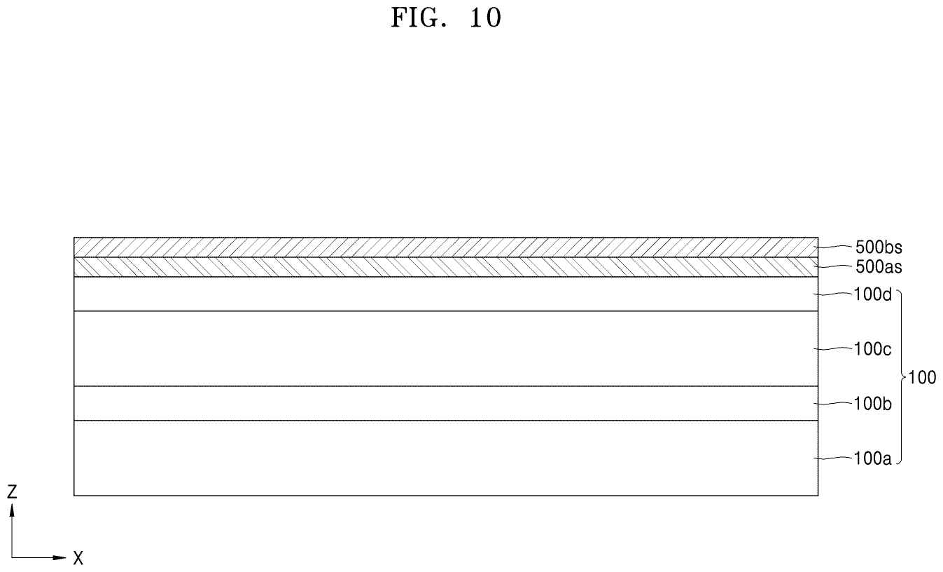

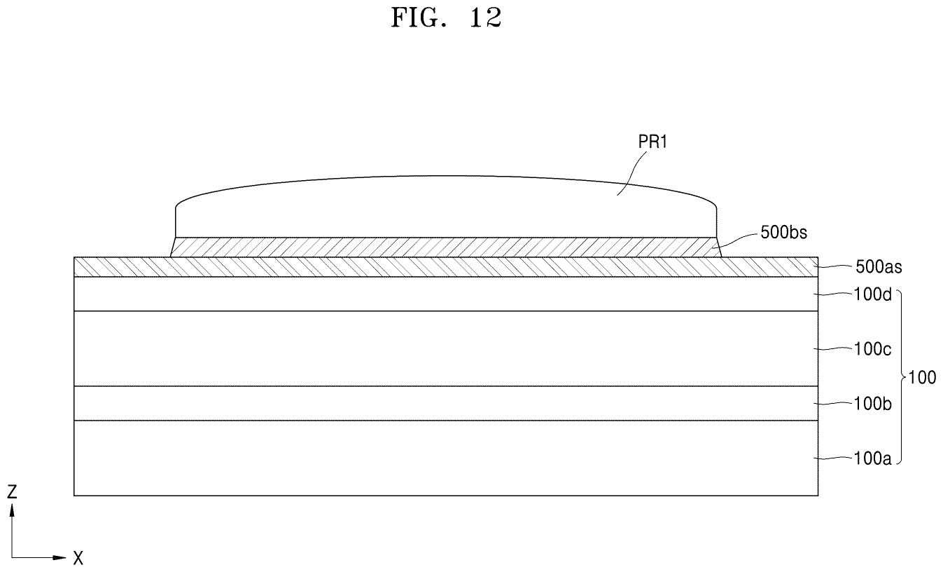

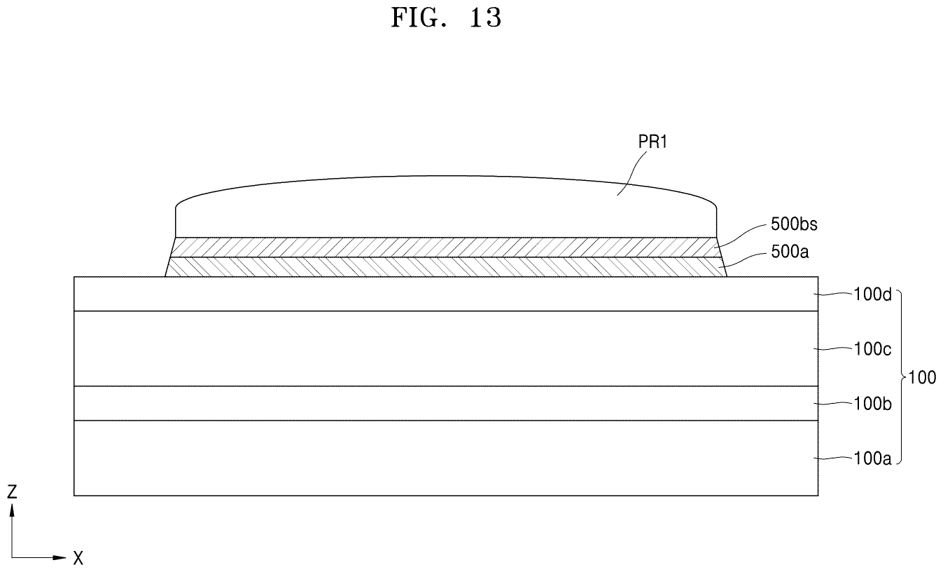

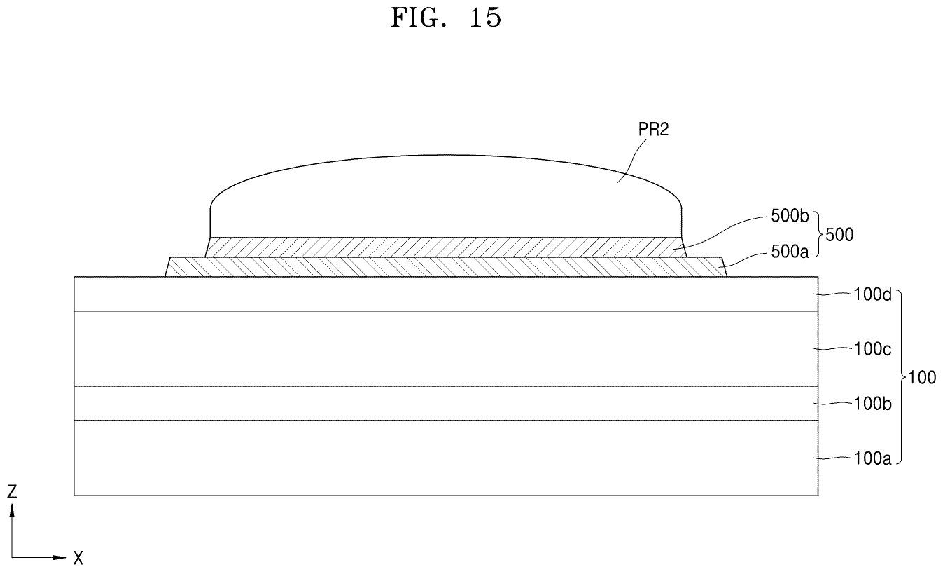

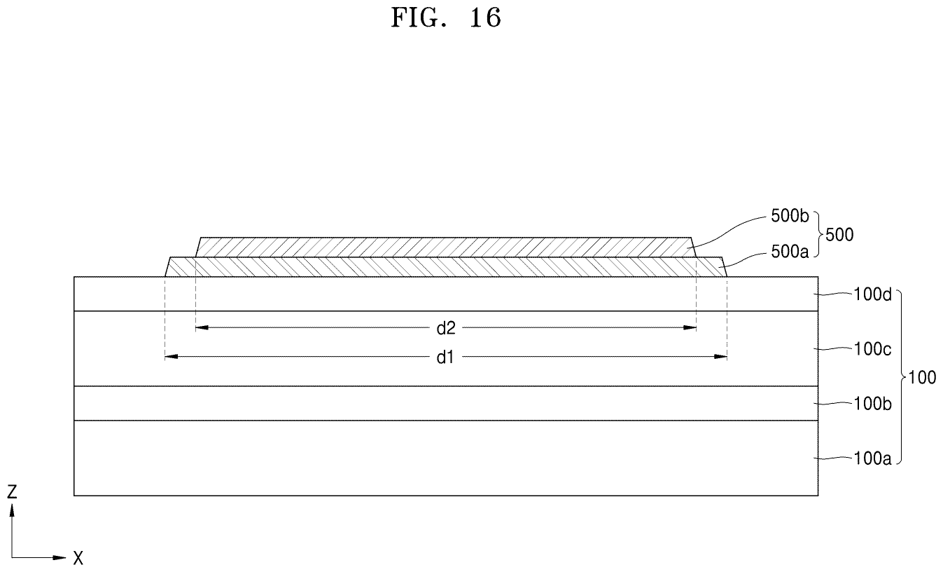

FIGS. 10 through 17 are cross-sectional views schematically illustrating a method of manufacturing a display apparatus, according to an embodiment.

Referring to FIG. 10, a first lower metal layer-forming material 500as may be disposed on the substrate 100. A second lower metal layer-forming material 500bs may be disposed on the first lower metal layer-forming material 500as. The first lower metal layer-forming material 500as and the second lower metal layer-forming material 500bs may include different materials from each other. According to an embodiment, when the first lower metal layer-forming material 500as includes titanium (Ti), the second lower metal layer-forming material 500bs may include molybdenum (Mo). According to another embodiment, when the first lower metal layer-forming material 500as includes molybdenum (Mo), the second lower metal layer-forming material 500bs may include titanium (Ti).

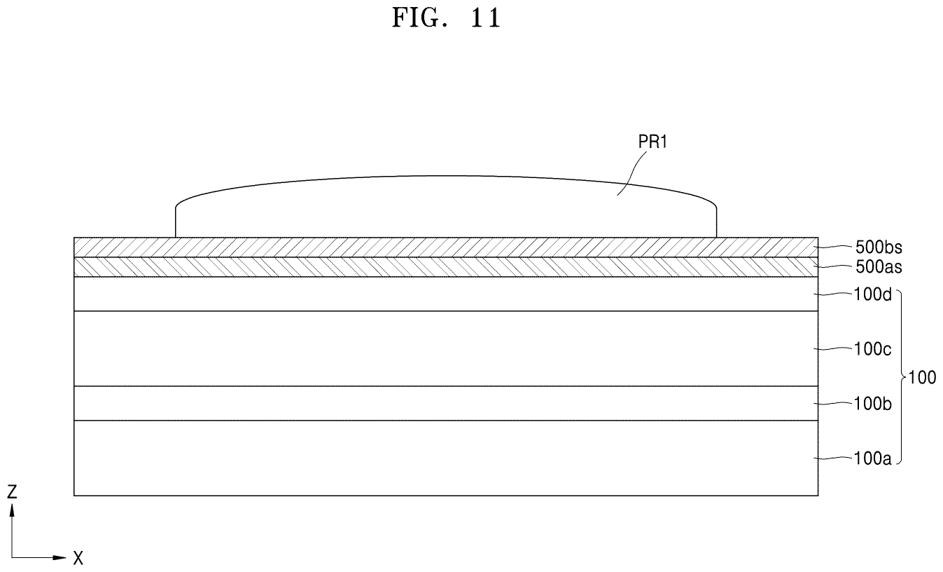

FIGS. 11 through 13 are cross-sectional views schematically illustrating a first etching operation of forming the first lower metal layer 500a. Referring to FIGS. 11 through 13, a first photoresist PR1 may be disposed on at least a portion of the second lower metal layer-forming material 500bs. A portion of the second lower metal layer-forming material 500bs on which the first photoresist PR1 is not disposed may be etched. Thereafter, the first lower metal layer 500a may be formed by etching the portion of the first lower metal layer-forming material 500as on which the first photoresist PR1 is not disposed. Next, the first photoresist PR1 may be removed. Because materials respectively included in the first lower metal layer-forming material 500as and the second lower metal layer-forming material 500bs are different from each other, atmospheres in which the first lower metal layer-forming material 500as and the second lower metal layer-forming material 500bs are etched, respectively, may be different from each other. Because the first lower metal layer-forming material 500as and the second lower metal layer-forming material 500bs are etched in different atmospheres, an edge portion of the first lower metal layer 500a and an edge portion of the second lower metal layer 500b may form a step after first and second etching operations.

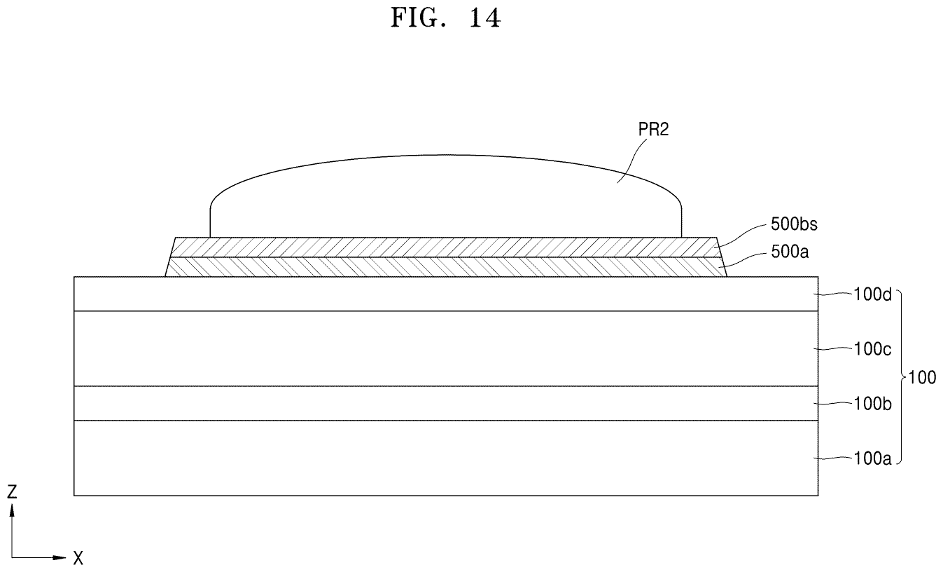

FIGS. 14 through 16 are cross-sectional views schematically illustrating a second etching operation of forming the second lower metal layer 500b. Referring to FIGS. 14 through 16, a second photoresist PR2 may be disposed on at least a portion of the second lower metal layer-forming material 500bs. The second lower metal layer 500b may be formed by etching the portion of the second lower metal layer-forming material 500bs on which the second photoresist PR2 is not disposed. Thereafter, the second photoresist PR2 may be removed.

In not only the second etching operation but also the first etching operation, at least a portion of the second lower metal layer-forming material 500bs may be further etched so that the edge portion of the second lower metal layer 500b and the edge portion of the first lower metal layer 500a may form a step. In other words, the longest length d1 of the first lower metal layer 500a in the first direction (e.g., the x direction or the −x direction) may be greater than the longest length d2 of the second lower metal layer 500b in the first direction (e.g., the x direction or the −x direction).

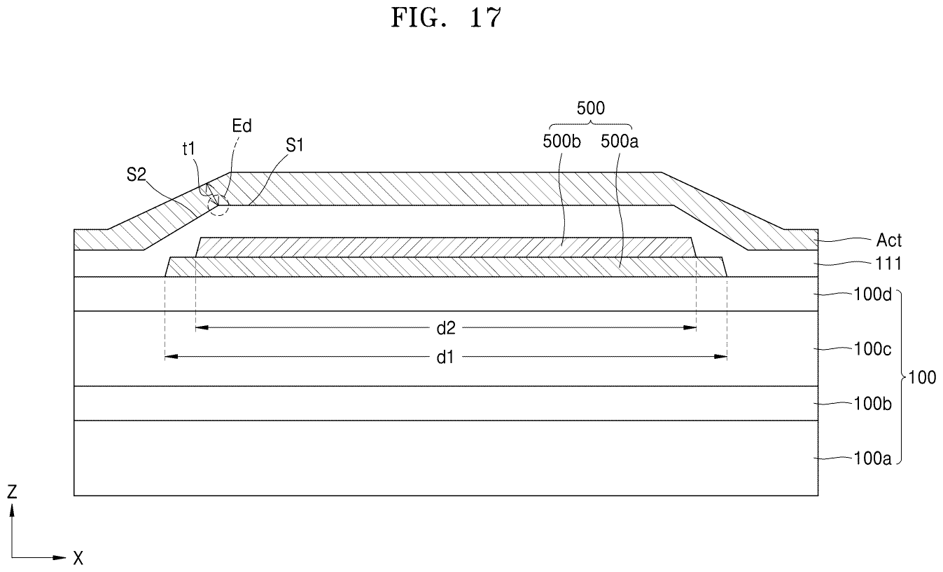

Referring to FIG. 17, the buffer layer 111 may be formed on the second lower metal layer 500b. A lateral surface of the buffer layer 111 may be provided as an inclined surface. The semiconductor layer Act may be formed on the buffer layer 111. A lateral surface of the semiconductor layer Act may also be provided as an inclined surface.

The thickness t2 of the semiconductor layer Act at the edge Ed where the top surface S1 of the buffer layer 111 farthest from the substrate 100 and the lateral surface S2 of the buffer layer 111 meet each other may be about 320 Å to about 480 Å. Because the thickness t2 of the semiconductor layer Act at the edge Ed where the top surface S1 of the buffer layer 111 farthest from the substrate 100 and the lateral surface S2 of the buffer layer 111 meet each other is about 320 Å to about 480 Å, membrane rupture of the semiconductor layer Act due to hydrogen (H₂) diffused into the semiconductor layer Act in the second base layer 100c due to the thermal energy accumulated at an interface between the second base layer 100c and the second barrier layer 100d may be prevented in a process of forming the semiconductor layer Act by radiating a laser to a semiconductor layer-forming material.

According to an embodiment as described above, a display apparatus having an improved reliability and an improved quality may be realized. Of course, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first lower metal layer disposed on the substrate;
a second lower metal layer disposed on the first lower metal layer and forming a step with an edge portion of the first lower metal layer;
a buffer layer disposed on the second lower metal layer; and
a semiconductor layer disposed on the buffer layer,
wherein a thickness of the semiconductor layer at an edge where a top surface of the buffer layer farthest from the substrate and a lateral surface of the buffer layer meet each other is about 320 angstroms (Å) to about 480 Å.

2. The display apparatus of claim 1, wherein a lateral surface of the first lower metal layer is provided as an inclined surface.

3. The display apparatus of claim 2, wherein a lateral surface of the second lower metal layer is provided as an inclined surface.

4. The display apparatus of claim 3, wherein the lateral surface of the first lower metal layer and the lateral surface of the second lower metal layer are provided in positive taper shapes.

5. The display apparatus of claim 1, wherein a lateral surface of the semiconductor layer is provided as an inclined surface.

6. The display apparatus of claim 1, wherein a longest length of the first lower metal layer in a first direction is greater than a longest length of the second lower metal layer in the first direction.

7. The display apparatus of claim 1, wherein
the first lower metal layer includes titanium (Ti), and
the second lower metal layer includes molybdenum (Mo).

8. The display apparatus of claim 1, wherein
the first lower metal layer includes molybdenum (Mo), and
the second lower metal layer includes titanium (Ti).

9. The display apparatus of claim 1, further comprising a third lower metal layer disposed on the second lower metal layer and forming a step with an edge portion of the second lower metal layer.

10. The display apparatus of claim 9, wherein
a lateral surface of the first lower metal layer, a lateral surface of the second lower metal layer, and a lateral surface of the third lower metal layer are provided as inclined surfaces.

11. The display apparatus of claim 10, wherein the lateral surface of the first lower metal layer, the lateral surface of the second lower metal layer, and the lateral surface of the third lower metal layer are provided in positive taper shapes.

12. The display apparatus of claim 9, wherein
a longest length of the first lower metal layer in a first direction is greater than a longest length of the second lower metal layer in the first direction, and
the longest length of the second lower metal layer in the first direction is greater than a longest length of the third lower metal layer in the first direction.

13. The display apparatus of claim 9, wherein
the first lower metal layer and the third lower metal layer include molybdenum (Mo), and
the second lower metal layer includes titanium (Ti).

14. The display apparatus of claim 9, wherein
the first lower metal layer and the third lower metal layer include titanium (Ti), and
the second lower metal layer includes molybdenum (Mo).

15. A method of manufacturing a display apparatus, the method comprising:
disposing a first lower metal layer-forming material on a substrate;
disposing a second lower metal layer-forming material on the first lower metal layer-forming material;
performing a first etching operation of forming a first lower metal layer by etching at least a portion of the first lower metal layer-forming material;
performing a second etching operation of forming a second lower metal layer by further etching at least a portion of the second lower metal layer-forming material;
forming a buffer layer on the first lower metal layer and the second lower metal layer; and
forming a semiconductor layer on the buffer layer,
wherein
a thickness of the semiconductor layer at an edge where a top surface of the buffer layer farthest from the substrate and a lateral surface of the buffer layer meet each other is about 320 Å to about 480 Å, and
the first lower metal layer-forming material and the second lower metal layer-forming material are different from each other.

16. The method of claim 15, wherein the first etching operation comprises:
disposing a first photoresist on at least a portion of the second lower metal layer-forming material;
forming the first lower metal layer by etching a portion of the first lower metal layer-forming material on which the first photoresist is not disposed;
etching a portion of the second lower metal layer-forming material on which the first photoresist is not disposed; and
removing the first photoresist.

17. The method of claim 15, wherein the second etching operation comprises:
disposing a second photoresist on at least a portion of the second lower metal layer-forming material;
forming the second lower metal layer by etching a portion of the second lower metal layer-forming material on which the second photoresist is not disposed; and
removing the second photoresist.

18. The method of claim 15, wherein
respective lateral surfaces of the first lower metal layer and the second lower metal layer are provided as inclined surfaces, and
the lateral surface of the first lower metal layer and the lateral surface of the second lower metal layer are provided in positive taper shapes.

19. The method of claim 15, wherein a lateral surface of the semiconductor layer is provided as an inclined surface.

20. The method of claim 15, wherein
the first lower metal layer-forming material includes molybdenum (Mo), and the second lower metal layer-forming material includes titanium (Ti), or
the first lower metal layer-forming material includes titanium (Ti), and the second lower metal layer-forming material includes molybdenum (Mo).
